(19) United States
(12) Patent Application Publication
(10) Pub. No.: US 2026/0164803 A1
(43) Pub. Date: Jun. 11, 2026

(54) DISPLAY DEVICE AND ELECTRONIC DEVICE INCLUDING THE SAME

(71) Applicant: Samsung Display Co., Ltd., Yongin-Si (KR)

(72) Inventors: Jong Hyun CHOI, Yongin-si (KR); Min Jeong OH, Yongin-si (KR)

(21) Appl. No.: 19/181,700

(22) Filed: Apr. 17, 2025

(30) Foreign Application Priority Data
Jun. 21, 2024 (KR) 10-2024-0081232
Aug. 22, 2024 (KR) 10-2024-0112455

(51) Int. Cl. H10D 86/40; H10D 86/60; H10K 59/121; H10K 59/131

(52) U.S. Cl. CPC H10D 86/441; H10D 86/60; H10K 59/1213; H10K 59/131

(57) ABSTRACT

A display device is disclosed that includes a second semiconductor pattern and a first second-transistor electrode connected to the second semiconductor pattern in a direction perpendicular to the second semiconductor pattern, a second conductive layer located on the first second-transistor electrode and connected to the first second-transistor electrode, a first bridge pattern located on the second conductive layer and connected to the second conductive layer, and a data line connected to the first bridge pattern to supply a data signal to the second semiconductor pattern. A first area where the second semiconductor pattern and the first second-transistor electrode are connected and a second area where the data line and the first bridge pattern are connected do not overlap.

### CROSS-REFERENCE TO RELATED PATENT APPLICATION

The present application claims priority under 35 U.S.C. § 119(a) to Korean patent application number 10-2024-0081232 filed on Jun. 21, 2024 and 10-2024-0112455 filed on Aug. 22, 2024, in the Korean Intellectual Property Office, the entire disclosure of which is incorporated by reference herein.

### BACKGROUND OF THE INVENTION

### 1. Field

The present disclosure relates to a display device and electronic device including the same.

### 2. Description of the Related Art

Display devices are gaining attention because they can be made lightweight and thin. Among display devices, an organic light-emitting display device is a self-luminous display device that displays an image using an organic light-emitting diode that emits light, and does not require a separate light source. In addition, the organic light-emitting display device is attracting attention as a next-generation display device due to its low power consumption, high brightness, and high response speed.

The above-described organic light-emitting display device includes a plurality of pixels, each of which includes an organic light-emitting diode, a plurality of transistors for driving the organic light-emitting diode, and at least one capacitor.

The content set forth above is only intended to help understanding of the background of the technical ideas of the present disclosure and, therefore, it should not be understood as corresponding to prior art known to those skilled in the art to which the present disclosure pertains.

### SUMMARY OF THE INVENTION

Embodiments of the present disclosure may provide a display device in which a short circuit between a data line and a transistor of a pixel is prevented.

A display device according to an embodiment of the present disclosure includes: a second semiconductor pattern and a first second-transistor electrode connected to the second semiconductor pattern in a direction perpendicular to the second semiconductor pattern; a second conductive layer located on the first second-transistor electrode and connected to the first second-transistor electrode; a first bridge pattern located on the second conductive layer and connected to the second conductive layer; and a data line connected to the first bridge pattern to supply a data signal to the second semiconductor pattern, wherein an area where the second semiconductor pattern and the first second-transistor electrode are connected and an area where the data line and the first bridge pattern are connected do not overlap.

An area where the first second-transistor electrode is connected to the second conductive layer may be spaced apart from an area where the first bridge pattern is connected to the second conductive layer by a first length in a direction in which the second conductive layer extends.

Each of the second semiconductor pattern and the second conductive layer may extend in a first direction, the first second-transistor electrode may extend in a third direction perpendicular to the first direction, and the second conductive layer may overlap the second semiconductor pattern in a partial area.

The first second-transistor electrode may electrically connect the second semiconductor pattern and the second conductive layer through a contact hole penetrating first and second insulating layers located between the second semiconductor pattern and the second conductive layer.

The second conductive layer may include a first layer containing titanium and disposed on the second insulating layer, and a second layer containing molybdenum and provided on the first layer.

The second conductive layer may include a first layer containing titanium and disposed on the second insulating layer, a second layer containing aluminum and provided on the first layer, and a third layer containing titanium and provided on the second layer.

The first bridge pattern may be connected to the second conductive layer through a contact hole penetrating the first organic layer located between the first bridge pattern and the second conductive layer.

A display device according to an embodiment of the present disclosure includes: a second semiconductor pattern and a first second-transistor electrode connected to the second semiconductor pattern in a direction perpendicular to the second semiconductor pattern; a first bridge pattern located on the first second-transistor electrode and connected to the first second-transistor electrode; and a data line connected to the first bridge pattern to supply a data signal to the second semiconductor pattern, wherein an area where the second semiconductor pattern and the first second-transistor electrode are connected and an area where the data line and the first bridge pattern are connected do not overlap.

An area where the first second-transistor electrode is connected to the first bridge pattern may be spaced apart from the area where the data line is connected to the first bridge pattern by a second length in a direction in which the first bridge pattern extends.

Each of the second semiconductor pattern and the first bridge pattern may extend in a first direction, the first second-transistor electrode may extend in a third direction perpendicular to the first direction, and the first bridge pattern may overlap the second semiconductor pattern in a partial area.

The first second-transistor electrode may be connected to the first bridge pattern through a contact hole penetrating a first insulating layer, a second insulating layer, and a first organic layer located between the first bridge pattern and the second semiconductor pattern.

The data line may be connected to the first bridge pattern through a contact hole penetrating the second organic layer located between the first bridge pattern and the data line.

A display device according to an embodiment of the present disclosure includes: a second semiconductor pattern and a second conductive layer located on the second semiconductor pattern; a fifth bridge pattern located on the second semiconductor pattern and the second conductive layer to electrically connect the second semiconductor pattern and the second conductive layer; a first bridge pattern located on the second conductive layer and connected to the second conductive layer; and a data line connected to the first bridge pattern to supply a data signal to the second semiconductor pattern, wherein an area where the second semiconductor pattern and the fifth bridge pattern are connected and an area where the data line and the first bridge pattern are connected do not overlap.

The fifth bridge pattern may include a first fifth-bridge pattern and a second fifth-bridge pattern and a third fifth-bridge pattern extending in a direction perpendicular to the second semiconductor pattern from the first fifth-bridge pattern, the second fifth-bridge pattern may be connected to the second conductive layer through a contact hole penetrating a first organic layer located between the first fifth-bridge pattern and the second conductive layer, and the third fifth-bridge pattern may be connected to the second semiconductor pattern through a contact hole penetrating a first insulating layer, a second insulating layer, and a first organic layer located between the first fifth-bridge pattern and the second semiconductor pattern.

The second conductive layer may include a first layer containing titanium and arranged on the second insulating layer, and a second layer containing molybdenum and provided on the first layer.

The second conductive layer may include a first layer containing titanium and arranged on the second insulating layer, a second layer containing aluminum and provided on the first layer, and a third layer containing titanium and provided on the second layer.

An area where the third fifth-bridge pattern may be connected to the second semiconductor pattern is spaced apart from an area where the first bridge pattern is connected to the second conductive layer by a third length in a direction in which the second conductive layer extends.

The first bridge pattern may be connected to the second conductive layer through a contact hole penetrating a first organic layer located between the first bridge pattern and the second conductive layer.

A electronic device according to an embodiment of the present disclosure includes: a processor to provide input image data; and a display device to display an image based on the input image data, the display device comprising: a second semiconductor pattern and a first second-transistor electrode connected to the second semiconductor pattern in a direction perpendicular to the second semiconductor pattern; a second conductive layer located on the first second-transistor electrode and connected to the first second-transistor electrode; a first bridge pattern located on the second conductive layer and connected to the second conductive layer; and a data line connected to the first bridge pattern to supply a data signal to the second semiconductor pattern, wherein a first area where the second semiconductor pattern and the first second-transistor electrode are connected and a second area where the data line and the first bridge pattern are connected do not overlap

According to embodiments of the present disclosure, it is possible to provide a display device in which a short circuit between a data line and a transistor of a pixel is prevented.

Effects according to embodiments are not limited to those exemplified above, and more diverse effects are included in the present specification.

### BRIEF DESCRIPTION OF THE DRAWINGS

FIG. 1 is a block diagram illustrating a display device according to embodiments of the present disclosure.

FIG. 2 is a circuit diagram illustrating a pixel according to embodiments of the present disclosure.

FIG. 3 is a partial cross-sectional view illustrating a stacked structure of second transistor, third transistor, and sixth transistor areas of the pixel of FIG. 2 according to an embodiment.

FIG. 4 is an enlarged view of an area X of FIG. 3.

FIG. 5 is a partial cross-sectional view illustrating a stacked structure of the second transistor, third transistor, and sixth transistor areas of the pixel of FIG. 2 according to an embodiment.

FIG. 6 is an enlarged view of an area Y of FIG. 5.

FIG. 7 is a partial cross-sectional view illustrating a stacked structure of the second transistor, third transistor, and sixth transistor areas of the pixel of FIG. 2 according to an embodiment.

FIG. 8 is an enlarged view of an area Z of FIG. 7.

FIG. 9 is a block diagram of an electronic device according to an embodiment.

FIG. 10 shows schematic views of various embodiments of an electronic device.

### DETAILED DESCRIPTION

Hereinafter, preferred embodiments will be described in detail with reference to the accompanying drawings. It should be noted that the following explanation describes only parts necessary to understand the operation according to the present disclosure, and descriptions of other parts will be omitted not to obscure the gist of the present disclosure. In addition, the present disclosure is not limited to the embodiments described herein, but may be embodied in other forms. However, the embodiment described herein is provided to explain in such detail as to facilitate implementation of the technical idea of the present disclosure to a person skilled in the art to which the present disclosure pertains.

Throughout the specification, if a part is “connected” to another part, this includes not only a case where they are “directly connected”, but also a case where they are “indirectly connected” with another element interposed therebetween. Terminology used herein is intended to describe specific embodiments and is not intended to limit the present disclosure. Throughout the specification, if a part “comprises” or “includes” a component, it means that it may further include other component rather than excluding other components unless the context indicates otherwise. “At least any one of X, Y, and Z” and “at least any one selected from a group of X, Y, and Z” may be interpreted as one X, one Y, one Z, or a combination of two or more of X, Y, and Z (e.g., XYZ, XYY, YZ, ZZ). As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Herein, terms such as first and second may be used to describe various components, but these components are not limited to these terms. These terms are used to distinguish one component from another component. Accordingly, a first component may be referred to as a second component without departing from the present disclosure.

Spatially relative terms such as “below” and “above” may be used for descriptive purposes, to describe a relationship between one element or feature and other element(s) or feature(s) as depicted in the drawings. Spatially relative terms are intended to encompass different directions in use, operation, or manufacturing, in addition to the directions depicted in the drawings. For example, if a device illustrated in a drawing is turned over, elements depicted as being positioned “below” other elements or features would instead be positioned “above” the other elements or features. Thus, in an embodiment, the term “below” may include both upward and downward directions. Additionally, the device may be oriented in other directions (e.g., rotated 90 degrees or in other directions), and the spatially relative terms used herein are interpreted accordingly.

Various embodiments are described with reference to drawings that illustrate ideal embodiments. Accordingly, it will be expected that the shapes may vary, for example, depending on tolerances or manufacturing techniques. Accordingly, the embodiments disclosed herein should not be construed as being limited to the specific shapes illustrated, but should be construed to include, for example, changes in shapes that occur as a result of manufacturing. As such, the shapes illustrated in the drawings may not depict the actual shapes of areas of the device, and the embodiments are not limited thereto.

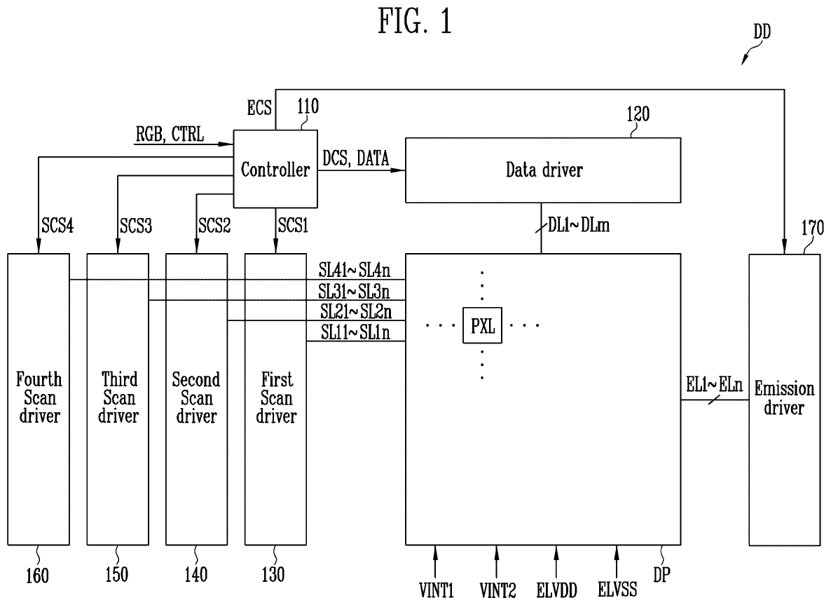

FIG. 1 is a block diagram illustrating a display device according to embodiments of the present disclosure.

Referring to FIG. 1, a display device DD may include a display panel DP, a controller 110, a data driver 120, first to fourth scan drivers 130, 140, 150, and 160, and an emission driver 170. In addition, the display device DD may further include a voltage supply unit not illustrated.

The display device DD may display an image at various driving frequencies depending on driving conditions. Here, the driving frequency is also called a screen scan rate or a screen refresh frequency, and indicates the frequency at which a display screen is refreshed as refresh count per second.

The display panel DP may include a plurality of pixels PXL. The display panel DP may be connected to data lines DL1 to DLm, first scan lines SL11 to SL1n, second scan lines SL21 to SL2n, third scan lines SL31 to SL3n, fourth scan lines SL41 to SL4n, and emission lines EL1 to ELn. In the display panel DP, a plurality of pixels PXL may be electrically connected to the data lines DL1 to DLm, first scan lines SL11 to SL1n, second scan lines SL21 to SL2n, third scan lines SL31 to SL3n, fourth scan lines SL41 to SL4n, and emission lines EL1 to ELn.

Each of the pixels PXL may receive voltages (for example, a first power supply voltage ELVDD, a second power supply voltage ELVSS, a first initialization voltage VINT1, a second initialization voltage VINT2, and the like) from the voltage supply unit.

The display panel DP may be various types, including an OLED (Organic Light-Emitting Diode) panel. The types of wires arranged in the display panel DP may vary depending on the pixel structure, panel type, and the like.

The controller 110 may control the operations of the data driver 120, the first to fourth scan drivers 130, 140, 150, and 160, and the emission driver 170. The controller 110 may receive control signals CTRL from the outside. In addition, the controller 110 may generate first to fourth scan control signals SCS1 to SCS4, a data control signal DCS, and an emission control signal ECS using the control signals CTRL.

The controller 110 may provide a first scan control signal SCS1 to the first scan driver 130 to apply scan signals to the first scan lines SL11 to SL1n according to a timing implemented in each frame. The first scan control signal SCS1 may include a first scan start pulse and clock signals. The first scan start pulse may control a first timing of the scan signal output from the first scan driver 130. The clock signals may be used to shift the first scan start pulse.

The controller 110 may provide a second scan control signal SCS2 to the second scan driver 140 to apply scan signals to the second scan lines SL21 to SL2n according to the timing implemented in each frame. The second scan control signal SCS2 may include a second scan start pulse and clock signals. The second scan start pulse may control a first timing of the scan signal output from the second scan driver 140. The clock signals may be used to shift the second scan start pulse.

The controller 110 may provide a third scan control signal SCS3 to the third scan driver 150 to apply scan signals to the third scan lines SL31 to SL3n according to the timing implemented in each frame. The third scan control signal SCS3 may include the third scan start pulse and clock signals. The third scan start pulse may control a first timing of the scan signal output from the third scan driver 150. The clock signals may be used to shift the third scan start pulse.

The controller 110 may provide a fourth scan control signal SCS4 to the fourth scan driver 160 to apply scan signals to the fourth scan lines SL41 to SL4n according to the timing implemented in each frame. The fourth scan control signal SCS4 may include a fourth scan start pulse and clock signals. The fourth scan start pulse may control a first timing of the scan signal output from the fourth scan driver 160. The clock signals may be used to shift the fourth scan start pulse.

The controller 110 may receive an image signal RGB from the outside. The controller 110 may provide the image data signal DATA, which is converted from the image signal RGB to the interface specifications of the data driver 120, to the data driver 120. The controller 110 may provide a data control signal DCS to the data driver 120 to apply data voltages to the data lines DL1 to DLm. The data control signal DCS may include a source start pulse and clock signals. The source start pulse may control a sampling start time of data. The clock signals may be used to control a sampling operation.

The controller 110 may provide the emission control signal ECS to the emission driver 170 to apply emission signals to the emission lines EL1 to ELn according to a timing implemented in each frame. The emission control signal ECS may include an emission control start pulse and clock signals. The emission control start pulse may control a first timing of an emission control signal output from the emission driver 170. The clock signals may be used to shift the emission control start pulse.

The controller 110 may be a timing controller used in conventional display technology, or may be a control device capable of performing other control functions, including a timing controller.

The data driver 120 may output data signals to the data lines DL1 to DLm. For example, the data driver 120 may receive the data control signal DCS and the image data signal DATA from the controller 110. The data driver 120 may convert the image data signal DATA into data signals and output the data signals to the data lines DL1 to DLm. Here, the data signals may be analog voltages corresponding to the grayscale values of the image data signal DATA. That is, when a specific scan line is selected by the first scan driver 130, the data driver 120 may supply analog data voltages to the data lines DL1 to DLm.

The first scan driver 130 may receive the first scan control signal SCS1 from the controller 110. The first scan driver 130 may output scan signals to the first scan lines SL11 to SL1n. For example, the first scan driver 130 may sequentially supply scan signals to the first scan lines SL11 to SL1n according to the first scan control signal SCS1 from the controller 110. When the scan signals are sequentially supplied from the first scan driver 130, the pixels PXL may be selected in units of horizontal lines (or pixel rows). Data signals may be supplied to the pixels PXL. That is, the scan signals supplied from the first scan driver 130 may be signals used for data writing.

The second scan driver 140 may receive the second scan control signal SCS2 from the controller 110. The second scan driver 140 may output scan signals to the second scan lines SL21 to SL2n. For example, the second scan driver 140 may sequentially supply scan signals to the second scan lines SL21 to SL2n according to the second scan control signal SCS2 from the controller 110. The scan signals supplied from the second scan driver 140 may be supplied for initialization or threshold voltage (Vth) compensation of transistors and capacitors included in the pixels PXL. When the scan signals are supplied from the second scan driver 140, the pixels PXL may perform threshold voltage compensation or initialization operations.

The third scan driver 150 may receive the third scan control signal SCS3 from the controller 110. The third scan driver 150 may output scan signals to the third scan lines SL31 to SL3n. For example, the third scan driver 150 may sequentially supply scan signals to the third scan lines SL31 to SL3n according to the third scan control signal SCS3 from the controller 110. The scan signals supplied from the third scan driver 150 may be supplied for initializing the driving transistors included in the pixels PXL and initializing the capacitors included in the pixels PXL. When the scan signals are supplied from the third scan driver 150, an initialization operation of the driving transistors or the initialization operation of the capacitors may be performed.

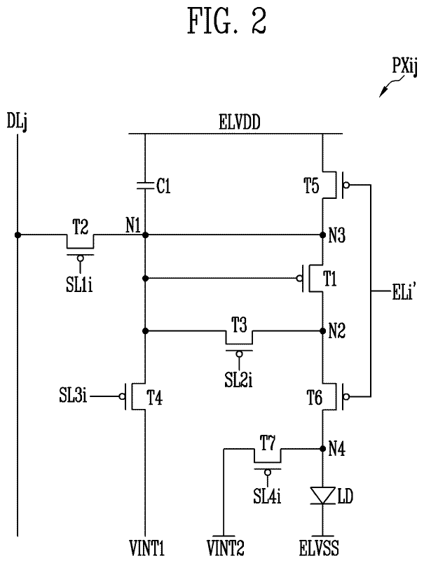

The fourth scan driver 160 may receive the fourth scan control signal SCS4 from the controller 110. The fourth scan driver 160 may output scan signals to the fourth scan lines SL41 to SL4n. The fourth scan driver 160 may sequentially supply scan signals to the fourth scan lines SL41 to SL4n according to the fourth scan control signal SCS4 from the controller 110. The scan signals supplied from the fourth scan driver 160 may be supplied for initializing the light-emitting elements (LD, see FIG. 2) included in the pixels PXL and supplying a predetermined bias voltage (for example, on-bias voltage) to the source electrode of the driving transistor included in the pixels PXL. When the scan signals are supplied from the fourth scan driver 160, the pixels PXL may perform the initialization operation of the light-emitting elements LD and the bias voltage supply operation.

The emission driver 170 may receive the emission control signal ECS from the controller 110. The emission driver 170 may output emission signals to the emission lines EL1 to ELn. The emission driver 170 may sequentially supply emission signals to the emission lines EL1 to ELn according to the emission control signal ECS from the controller 110.

Meanwhile, in FIG. 1, for convenience of explanation, the data driver 120, the first to fourth scan drivers 130, 140, 150, and 160, and the emission driver 170 are illustrated as separate components, but the present disclosure is not limited thereto. That is, at least some of the data driver 120, the first to fourth scan drivers 130, 140, 150, and 160, and the emission driver 170 may be integrated into one driving circuit, module, or the like.

The voltage supply unit may receive a voltage control signal from the controller 110. The voltage supply unit may supply voltages (for example, the first power supply voltage ELVDD, the second power supply voltage ELVSS, the first initialization voltage VINT1, the second initialization voltage VINT2, and the like) to the display panel DP in response to the voltage control signal. In an embodiment, the first power supply voltage ELVDD may be higher than the second power supply voltage ELVSS.

The first power supply voltage ELVDD and the second power supply voltage ELVSS may be voltages for driving the light-emitting element LD. The first and second initialization voltages VINT1 and VINT2 may be voltages for initializing each of the pixels PXL. For example, the anode of the light-emitting element LD included in each of the pixels PXL may be initialized by the first and second initialization voltages VINT1 and VINT2. The first and second initialization voltages VINT1 and VINT2 may be negative voltages.

FIG. 2 is a circuit diagram illustrating a pixel according to embodiments of the present disclosure. In FIG. 2, for convenience of explanation, a pixel PXij located on an i-th horizontal line (or an i-th pixel row) and connected to a j-th data line DLj is illustrated.

Referring to FIG. 2, the pixel PXij may include a light-emitting element LD, first to seventh transistors T1 to T7, and a first capacitor C1.

A first electrode (or anode) of the light-emitting element LD may be connected to a second electrode (for example, a drain electrode) of the first transistor T1 (i.e. a second node N2) via a sixth transistor T6, and a second electrode (or cathode) of the light-emitting element LD may be connected to a power line to which a second power supply voltage ELVSS is supplied.

The first transistor T1 may be connected to a power line to which a first power supply voltage ELVDD is supplied via a fifth transistor T5. The first transistor T1 may be connected to the first electrode of the light-emitting element LD via the sixth transistor T6. The first transistor T1 may generate a driving current and provide it to the light-emitting element LD. The gate electrode of the first transistor T1 may be connected to a first node N1. The first transistor T1 may function as a driving transistor of the pixel PXij. The first transistor T1 may control the amount of current flowing through the light-emitting element LD in response to the voltage applied to the first node N1.

The first capacitor C1 may be connected between the first node N1 (corresponding to the gate electrode of the first transistor T1) and the power line to which the first power supply voltage ELVDD is supplied. The first capacitor C1 may store a voltage corresponding to a voltage difference between the voltage of the first node N1 and the first power supply voltage ELVDD.

The second transistor T2 may be connected between the j-th data line DLj and the first node N1. The second transistor T2 may include a gate electrode that receives a scan signal. For example, the gate electrode of the second transistor T2 may be connected to the 1i-th scan line SL1i to receive a scan signal from the first scan driver 130. The second transistor T2 may be turned on when the scan signal is supplied from the first scan driver 130 to electrically connect the j-th data line DLj and the first node N1. Accordingly, the data signal (or data voltage) may be transmitted to the first node N1.

The third transistor T3 may be connected between the first node N1 corresponding to the gate electrode of the first transistor T1 and the second electrode of the first transistor T1 (i.e. the second node N2). The third transistor T3 may include a gate electrode that receives a scan signal. For example, the gate electrode of the third transistor T3 may be connected to the 2i-th scan line SL2i to receive a scan signal from the second scan driver 140. The third transistor T3 may be turned on when the scan signal is supplied from the second scan driver 140, thereby electrically connecting the first node N1 and the second node N2.

The fourth transistor T4 may be connected between the first node N1 and a power line to which the first initialization voltage VINT1 is supplied. The fourth transistor T4 may include a gate electrode that receives a scan signal. For example, the gate electrode of the fourth transistor T4 may be connected to the 3i-th scan line SL3i, and may receive a scan signal from the third scan driver 150. The fourth transistor T4 may be turned on when the scan signal is supplied from the third scan driver 150, and may electrically connect the first node N1 and the power line to which the first initialization voltage VINT1 is supplied. As the fourth transistor T4 is turned on, the first initialization voltage VINT1 may be supplied to the first node N1, and the voltage of the first node N1 may be initialized to the first initialization voltage VINT1.

The fifth transistor T5 may be connected between the power line to which the first power supply voltage ELVDD is supplied and the first electrode of the first transistor T1 (i.e. the third node N3). The fifth transistor T5 may include a gate electrode that receives an emission signal. For example, the gate electrode of the fifth transistor T5 may be connected to the i-th emission line ELi, and may receive an emission signal from the emission driver 170. The fifth transistor T5 may be turned on when the emission signal is supplied to the i-th emission line Eli, and may be turned off in other cases. The fifth transistor T5 in the turned-on state may connect the first electrode of the first transistor T1 to a power line to which the first power supply voltage ELVDD is supplied.

The sixth transistor T6 may be connected between the second node N2 corresponding to the second electrode of the first transistor T1 and the anode of the light-emitting element LD (i.e. the fourth node N4). The sixth transistor T6 may include a gate electrode that receives an emission signal. For example, the gate electrode of the sixth transistor T6 may be connected to the i-th emission line ELi, and may receive an emission signal from the emission driver 170. The fifth transistor T5 may be turned on when an emission signal is supplied to the i-th emission line Eli, and may be turned off otherwise. The fifth transistor T5 in the turned-on state may be electrically connected between the second node N2 and the fourth node N4.

The seventh transistor T7 may be connected between the first electrode of the light-emitting element LD (i.e. the fourth node N4) and the power line to which the second initialization voltage VINT2 is supplied. The seventh transistor T7 may include a gate electrode that receives a scan signal. For example, the seventh transistor T7 may be connected to the 4i-th scan line SL4i and may receive a scan signal from the fourth scan driver 160. The seventh transistor T7 may be turned on when a scan signal is supplied from the fourth scan driver 160, and may be electrically connected between the fourth node N4 and the power line to which the second initialization voltage VINT2 is supplied. As the seventh transistor T7 is turned on, the second initialization voltage VINT2 is supplied to the fourth node N4, and the voltage of the fourth node N4 may be initialized to the second initialization voltage VINT2. When the second initialization voltage VINT2 is supplied to the anode of the light-emitting element LD, the parasitic capacitor of the light-emitting element LD may be discharged. As the residual voltage charged in the parasitic capacitor is discharged (removed), unintended micro-emission may be prevented. Accordingly, the black expression capability of the pixel PXij may be improved. By separating the initialization operation of the gate electrode of the first transistor T1 (i.e. the first node N1) and the initialization operation of the anode of the light-emitting element LD (i.e. the fourth node N4), it is possible to prevent the light-emitting element LD from unintentionally emitting light during the initialization operation of the gate electrode of the first transistor T1 (i.e. the first node N1).

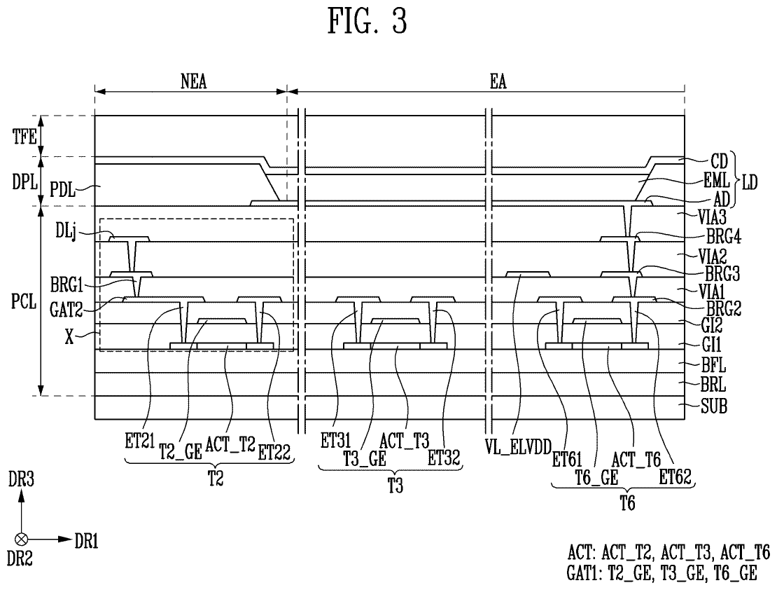

FIG. 3 is a partial cross-sectional view illustrating the stacked structure of the second transistor, third transistor, and sixth transistor areas of the pixel of FIG. 2 according to an embodiment.

Referring to FIG. 3, a pixel circuit layer PCL, a display element layer DPL, and a thin film encapsulation layer TFE may be sequentially arranged on a base layer SUB (or substrate).

The pixel circuit layer PCL may include a barrier layer BRL, a buffer layer BFL, a semiconductor layer ACT, a first insulating layer GI1, a first conductive layer GAT1, a second insulating layer GI2, a first organic layer VIA1, a second organic layer VIA2, and a third organic layer VIA3.

In the pixel circuit layer PCL, the barrier layer BRL, the buffer layer BFL, the semiconductor layer ACT, the first insulating layer GI1, the first conductive layer GAT1, the second insulating layer GI2, the first organic layer VIA1, the second organic layer VIA2, and the third organic layer may be sequentially stacked on the base layer SUB in a third direction DR3.

The second transistor T2 may include a second semiconductor pattern ACT_T2, a gate pattern T2_GE of the second transistor T2, a first second-transistor electrode ET21, and a second second-transistor electrode ET22.

The third transistor T3 may include a third semiconductor pattern ACT_T3, a gate pattern T3_GE of the third transistor T3, a first third-transistor electrode ET31, and a second third-transistor electrode ET32.

The sixth transistor T6 may include a sixth semiconductor pattern ACT_T6, a gate pattern T6_GE of the sixth transistor T6, a first sixth-transistor electrode ET61, and a second sixth-transistor electrode ET62.

The base layer SUB may be made of an insulating material such as glass or resin. In addition, the base layer SUB may be made of a material having flexibility so that it may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the materials forming the base layer SUB are not limited to the above-described embodiments.

The barrier layer BRL may be arranged on the entire surface of the base layer SUB. The barrier layer BRL may block unnecessary components such as moisture or oxygen from the outside from entering the light-emitting element. For example, the barrier layer BRL may be made of silicon oxide (SiOx).

The buffer layer BFL may be arranged on the entire surface of the barrier layer BRL. The buffer layer BFL may prevent diffusion of impurity ions and penetration of moisture or external air. The buffer layer BFL may be an inorganic insulating film containing an inorganic material. The buffer layer BFL may be provided as a single film, but may also be provided as a multi-film consisting of at least two films or more.

The semiconductor layer ACT may be disposed on the buffer layer BFL. The semiconductor layer ACT may be disposed between the buffer layer BFL and the first insulating layer GI1. The semiconductor layer ACT may be an active layer forming a channel of the first to seventh transistors T1 to T7. The semiconductor layer ACT may include a source area (or a first area) and a drain area (or a second area) that contact a first electrode (for example, a source electrode) and a second electrode (for example, a drain electrode) of each of the first to seventh transistors T1 to T7. An area between the source area and the drain area may be a channel area. For example, the semiconductor layer ACT may include a second semiconductor pattern ACT_T2 forming a second transistor T2. For example, the semiconductor layer ACT may include a third semiconductor pattern ACT_T3 forming a third transistor T3. For example, the semiconductor layer ACT may include a sixth semiconductor pattern ACT_T6 forming the sixth transistor T6.

The second semiconductor pattern ACT_T2 may include a first area contacting the first second-transistor electrode ET21, a second area contacting the second second-transistor electrode ET22, and a channel area located between the first and second areas. The second semiconductor pattern ACT_T2 may be a semiconductor pattern made of polysilicon. The channel area of the second semiconductor pattern ACT_T2 may be a semiconductor pattern that is not doped with impurities and may be an intrinsic semiconductor. The first and second areas of the second semiconductor pattern ACT_T2 may be semiconductor patterns doped with impurities.

The third semiconductor pattern ACT_T3 may include a first area contacting the first third-transistor electrode ET31, a second area contacting the second third-transistor electrode ET32, and a channel area located between the first and second areas. The third semiconductor pattern ACT_T3 may be a semiconductor pattern made of polysilicon. The channel area of the third semiconductor pattern ACT_T3 may be a semiconductor pattern that is not doped with impurities and may be an intrinsic semiconductor. The first and second areas of the third semiconductor pattern ACT_T3 may be semiconductor patterns that are doped with impurities.

The sixth semiconductor pattern ACT_T6 may include a first area contacting the first sixth-transistor electrode ET61, a second area contacting the second sixth-transistor electrode ET62, and a channel area located between the first and second areas. The sixth semiconductor pattern ACT_T6 may be a semiconductor pattern made of polysilicon. The channel area of the sixth semiconductor pattern ACT_T6 may be a semiconductor pattern that is not doped with impurities and may be an intrinsic semiconductor. The first and second areas of the sixth semiconductor pattern ACT_T6 may be semiconductor patterns that are doped with impurities.

The first insulating layer GI1 may be disposed on the semiconductor layer ACT. The first insulating layer GI1 may be an inorganic insulating film containing an inorganic material. For example, the first insulating layer GI1 may contain the same material as the buffer layer BFL or may contain one or more materials selected from the materials exemplified as the constituent materials of the buffer layer BFL. According to an embodiment, the first insulating layer GI1 may be formed of an organic insulating film containing an organic material. The first insulating layer GI1 may be provided as a single film, but may also be provided as a multi-film consisting of at least two films or more.

The first conductive layer GAT1 may be disposed on the first insulating layer GI1. The first conductive layer GAT1 may include a gate pattern T2_GE of the second transistor T2, a gate pattern T3_GE of the third transistor T3, and a gate pattern T6_GE of the sixth transistor T6.

The first conductive layer GAT1 may contain one or more metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu). The first conductive layer GAT1 may have a single-film or multi-film structure, and for example, the first conductive layer GAT1 may have a single-film structure including molybdenum (Mo).

The second insulating layer GI2 may be disposed on the first insulating layer GI1 and the first conductive layer GAT1. The second insulating layer GI2 may be disposed substantially over the entire surface of the base layer SUB. The second insulating layer GI2 may contain the same material as the first insulating layer GI1 or may contain one or more materials selected from the materials exemplified as the constituent materials of the first insulating layer GI1.

The second conductive layer GAT2 may be disposed on the second insulating layer GI2. The second conductive layer GAT2 may be connected to the first second-transistor electrode ET21 and electrically connected to the first second-transistor electrode ET21.

In embodiments, the second conductive layer GAT2 may contain various materials. For example, the second conductive layer GAT2 may contain titanium (Ti) and may be composed of a first layer disposed on the second insulating layer GI2 and a second layer containing molybdenum (Mo) and provided on the first layer. For example, the second conductive layer GAT2 may be composed of a first layer containing titanium (Ti) and disposed on the second insulating layer GI2, a second layer containing aluminum (Al) and provided on the first layer, and a third layer containing titanium (Ti) and provided on the second layer.

The second bridge pattern BRG2 may overlap the second area of the sixth semiconductor pattern ACT_T6. The second bridge pattern BRG2 may be connected to the second area of the sixth semiconductor pattern ACT_T6 through a contact hole penetrating the first insulating layer GI1 and the second insulating layer GI2. In addition, the second bridge pattern BRG2 may form the second sixth-transistor electrode ET62 of the sixth transistor.

The first organic layer VIA1 may be disposed on the second insulating layer GI2, the second conductive layer GAT2, and the second bridge pattern BRG2. The first organic layer VIA1 may be arranged substantially over the entire surface of the base layer SUB.

The first organic layer VIA1 may contain an organic insulating material such as polyacrylates resin, epoxy resin, phenolic resin, polyamides resin, polyimides resin, unsaturated polyesters resin, polyphenyleneethers resin, polyphenylenesulfides resin, or benzocyclobutene (BCB).

The first bridge pattern BRG1 may overlap the second conductive layer GAT2 and may be connected to the second conductive layer GAT2 through a contact hole penetrating the first organic layer VIA1.

The third bridge pattern BRG3 may overlap the second bridge pattern BRG2. The third bridge pattern BRG3 may be connected to the second bridge pattern BRG2 through a contact hole penetrating the first insulating layer GI1 and the second insulating layer GI2.

The power line VL_ELVDD of the second power supply voltage ELVDD may be arranged on the first organic layer VIA1.

The second organic layer VIA2 may be arranged on the first organic layer VIA1, the first bridge pattern BRG1, the third bridge pattern BRG3, and the power line VL_ELVDD of the second power supply voltage ELVDD. The second organic layer VIA2 may be arranged substantially over the entire surface of the base layer SUB. The second organic layer VIA2 may contain the same material as the first organic layer VIA1 or one or more materials selected from the materials exemplified as the constituent materials of the first organic layer VIA1.

The fourth bridge pattern BRG4 may overlap the third bridge pattern BRG3. The fourth bridge pattern BRG4 may be connected to the third bridge pattern BRG3 through a contact hole penetrating the second insulating layer GI2.

The j-th data line DLj may be arranged on the second organic layer VIA2. The j-th data line DLj may overlap the first bridge pattern BRG1. The j-th data line DLj may be connected to the first bridge pattern BRG1 through a contact hole penetrating the second organic layer VIA2. In other words, the j-th data line DLj may be electrically connected to the first second-transistor electrode ET21 through the first bridge pattern BRG1 and the second conductive layer GAT2.

The third organic layer VIA3 may be arranged on the j-th data line DLj and the fourth bridge pattern BRG4. The third organic layer VIA3 may be arranged substantially over the entire surface of the base layer SUB. The third organic layer VIA3 may contain the same material as the first organic layer VIA1 or may contain one or more materials selected from the materials exemplified as the constituent materials of the first organic layer VIA1.

The display element layer DPL may include an anode AD, a pixel defining layer PDL, an emission layer EML, and a cathode CD. The anode AD, the pixel defining layer PDL, the emission layer EML, and the cathode CD may be sequentially arranged or formed on the third organic layer VIA3.

The anode AD may be arranged on the third organic layer VIA3. The anode AD may be arranged corresponding to the emission area EA of each pixel. A non-emission area NEA may surround each pixel.

The anode AD may be connected to the fourth bridge pattern BRG4 through a contact hole penetrating the third organic layer VIA3. The anode AD may be connected to the second sixth-transistor electrode ET62 of the sixth transistor T6 through the third bridge pattern BRG3 and the fourth bridge pattern BRG4.

The anode AD may be made of a conductive material (or material) having a constant reflectivity. The conductive material (or material) may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and alloys thereof. According to an embodiment, the anode AD may include a transparent conductive material (or material). The transparent conductive material (or material) may include conductive oxides such as indium tin oxide (ITO), indium zinc oxide (IZO), zinc oxide (ZnO), indium gallium zinc oxide (IGZO), and indium tin zinc oxide (ITZO), and conductive polymers such as poly(3,4-ethylenedioxythiophene) (PEDOT).

The pixel defining layer PDL may be disposed or formed on the third organic layer VIA3 and the anode AD in the non-emission area NEA. The pixel defining layer PDL may partially overlap the edge of the anode AD in the non-emission area NEA. The pixel defining layer PDL may contain an insulating material including an inorganic material or an organic material. For example, the pixel defining layer PDL may include at least one layer of an inorganic film containing various inorganic insulating materials known in the art, such as silicon nitride (SiNx) or silicon oxide (SiOx). Alternatively, the pixel defining layer PDL may include at least one layer of an organic film containing various organic insulating materials known in the art, such as a photoresist film, or may be composed of a single layer or a plurality of layers of an insulator including a composite of organic and inorganic materials. That is, the constituent materials of the pixel defining layer PDL may be variously changed.

In an embodiment, the pixel defining layer PDL may be configured to contain at least one light-shielding material or a reflective material to prevent light leakage defects between pixels. According to an embodiment, the pixel defining layer PDL may contain a transparent material. As the transparent material, for example, polyamides resin, polyimides resin, and the like may be included, but the present disclosure is not limited thereto. According to an embodiment, a reflective material layer may be separately provided or formed on the pixel defining layer PDL to further improve the efficiency of light emitted from each pixel.

The emission layer EML may be disposed on the anode AD in the emission area EA. That is, the emission layer EML may be formed separately for each of the plurality of pixels PXL. The emission layer EML may include an organic material or an inorganic material to emit a predetermined color. For example, the pixel (PXij, see FIG. 2) may include first to third sub-pixels. Each of the first to third sub-pixels may emit red light, green light, and blue light.

However, the present disclosure is not limited thereto, and for example, the emission layer EML may be commonly arranged in a plurality of pixels PXL. At this time, the emission layer EML may emit white light.

A cathode CD may be arranged on the emission layer EML. The cathode CD may be commonly arranged in a plurality of pixels PXL.

The thin film encapsulation layer TFE may be arranged on the cathode CD. The thin film encapsulation layer TFE may be commonly arranged in a plurality of pixels PXL. In FIG. 3, the thin film encapsulation layer TFE is illustrated as directly covering the cathode CD, but a capping layer covering the cathode CD may be further arranged between the thin film encapsulation layer TFE and the cathode CD.

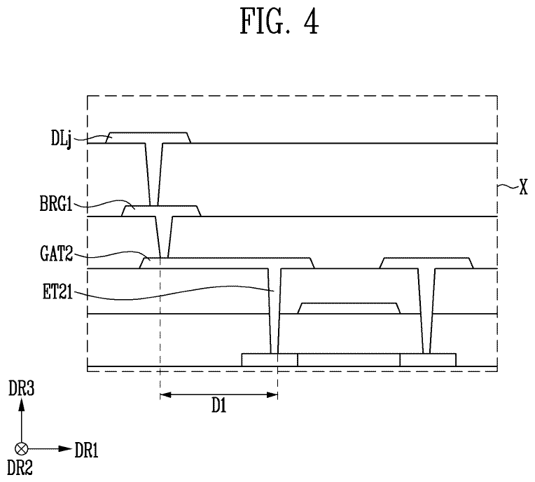

FIG. 4 is an enlarged view of the area X of FIG. 3.

Referring to FIGS. 3 and 4, the first area of the second semiconductor pattern ACT_T2 may be connected to the second conductive layer GAT2 through the first second-transistor electrode ET21. The first second-transistor electrode ET21 may extend in a direction perpendicular to the second semiconductor pattern ACT_T2 (i.e. in the third direction DR3).

The j-th data line DLj may be arranged on the second organic layer VIA2. The j-th data line DLj may overlap the first bridge pattern BRG1. The j-th data line DLj may be connected to the first bridge pattern BRG1 through a contact hole penetrating the second organic layer VIA2. The first bridge pattern BRG1 may overlap the second conductive layer GAT2 and may be connected to the second conductive layer GAT2 through a contact hole penetrating the first organic layer VIA1. The contact holes may be formed to extend in a direction perpendicular to the second semiconductor pattern ACT_T2 (i.e. in the third direction DR3).

The second conductive layer GAT2 may extend in the first direction DR1. The positions where the first bridge pattern BRG1 and the first second-transistor electrode ET21 are connected to the second conductive layer GAT2 may be spaced apart from each other by a first length D1 in the first direction DR1. Accordingly, the position where the j-th data line DLj and the first bridge pattern BRG1 are connected may not overlap the position where the first second-transistor electrode ET21 and the first area of the second semiconductor pattern ACT_21 are connected.

During use of the display device DD, an unintentional physical impact may occur at or near the pixel PXij in the third direction DR3 (or in the direction perpendicular to the base layer SUB). When this happens, the distance between the j-th data line DLj and the second semiconductor pattern ACT_T2 in the third direction DR3 may become shorter due to compression caused by the impact. If the j-th data line DLj and the second semiconductor pattern ACT_T2 are short-circuited with each other, the data signal may not be input, which may result in the pixel PXij appearing as a bright spot.

In an embodiment of the present disclosure, the position where the j-th data line DLj and the first bridge pattern BRG1 are connected may not overlap the position where the first second-transistor electrode ET21 and the first area of the second semiconductor pattern ACT_21 are connected. From this, the j-th data line DLj may be prevented from being short-circuited with the second semiconductor pattern ACT_21 due to an the unintentional physical impact. Furthermore, it is possible to prevent the data signal from not being input and being expressed as a bright spot due to a short circuit of the j-th data line DLj.

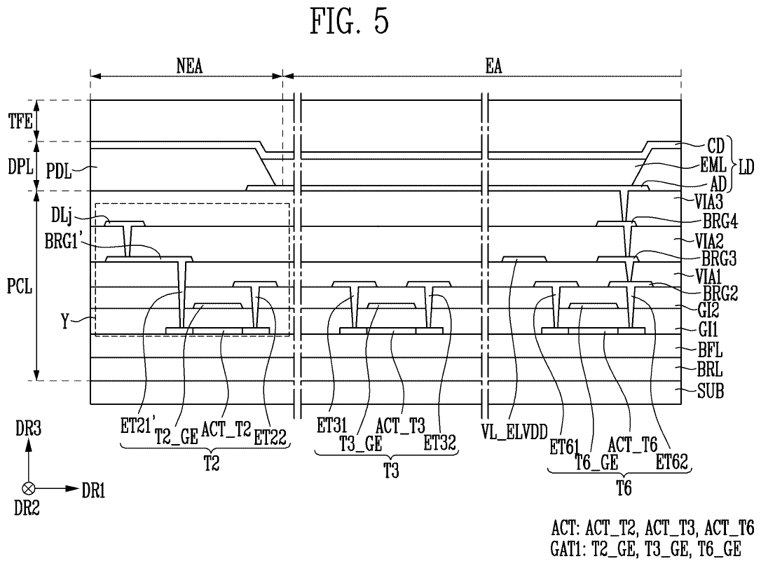

FIG. 5 is a partial cross-sectional view illustrating the stacked structure of the second transistor, third transistor, and sixth transistor areas of the pixel of FIG. 2 according to an embodiment.

Referring to FIG. 5, a pixel circuit layer PCL, a display element layer DPL, and a thin film encapsulation layer TFE may be sequentially arranged on a base layer SUB (or substrate).

The pixel circuit layer PCL may include a barrier layer BRL, a buffer layer BFL, a semiconductor layer ACT, a first insulating layer GI1, a first conductive layer GAT1, a second insulating layer GI2, a first organic layer VIA1, a second organic layer VIA2, and a third organic layer VIA3.

In the pixel circuit layer PCL, the barrier layer BRL, the buffer layer BFL, the semiconductor layer ACT, the first insulating layer GI1, the first conductive layer GAT1, the second insulating layer GI2, the first organic layer VIA1, the second organic layer VIA2, and the third organic layer may be sequentially stacked on the base layer SUB in a third direction DR3.

The second transistor T2 may include a second semiconductor pattern ACT_T2, a gate pattern T2_GE of the second transistor T2, a first second-transistor electrode ET21′, and a second second-transistor electrode ET22.

The third transistor T3 may include a third semiconductor pattern ACT_T3, a gate pattern T3_GE of the third transistor T3, a first third-transistor electrode ET31, and a second third-transistor electrode ET32.

The sixth transistor T6 may include a sixth semiconductor pattern ACT_T6, a gate pattern T6_GE of the sixth transistor T6, a first sixth-transistor electrode ET61, and a second sixth-transistor electrode ET62.

When comparing the embodiments of FIGS. 3 and 5, the embodiment of FIG. 5 may not include a second conductive layer GAT2. The embodiment of FIG. 5 may differ from the embodiment of FIG. 3 in the first second-transistor electrode ET21′ and the first bridge pattern BRG1'. Therefore, redundant descriptions may be omitted below.

The first bridge pattern BRG1′ may overlap the second semiconductor pattern ACT_T2 and may be connected to the second semiconductor pattern ACT_T2 through a contact hole penetrating the first organic layer VIA1, the first insulating layer GI1, and the second insulating layer GI2. More specifically, the first bridge pattern BRG1′ may be connected to the first area of the second semiconductor pattern ACT_T2. The contact hole penetrating the first organic layer VIA1, the first insulating layer GI1, and the second insulating layer GI2 may be formed to extend in a direction perpendicular to the second semiconductor pattern ACT_T2 (or, in the third direction DR3).

The first bridge pattern BRG1′ may have a shape that is further extended in the first direction DR1 compared to the first bridge pattern BRG1 of FIG. 3. In other words, the width of the first bridge pattern BRG1′ in the first direction DR1 may be larger than the width of the first bridge pattern BRG1 in the first direction DR1.

The j-th data line DLj may be electrically connected to the second semiconductor pattern ACT_T2 through the first bridge pattern BRG1′.

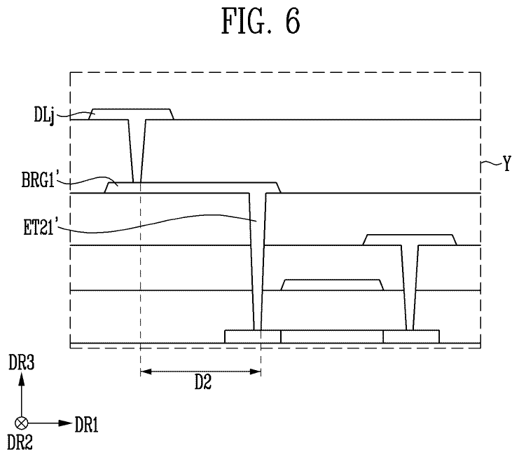

FIG. 6 is an enlarged view of the area Y of FIG. 5.

Referring to FIG. 6, the first area of the second semiconductor pattern ACT_T2 may be connected to an area of the first bridge pattern BRG1′.

In addition, the j-th data line DLj may be connected to another area of the first bridge pattern BRG1′.

Here, an area of the first bridge pattern BRG1′ may be spaced apart from the other area of the first bridge pattern BRG1′ in the first direction DR1 by a second length D2. Accordingly, the location where the j-th data line DLj and the first bridge pattern BRG1′ are connected may not overlap the location where the second semiconductor pattern ACT_T2 and the first bridge pattern BRG1′ are connected.

During use of the display device DD, an unintentional physical impact may occur at or near the pixel PXij in the third direction DR3 (or in the direction perpendicular to the base layer SUB). When this happens, the distance between the j-th data line DLj and the second semiconductor pattern ACT_T2 in the third direction DR3 may become shorter due to the compression caused by the impact. If the j-th data line DLj and the second semiconductor pattern ACT_T2 are short-circuited with each other, the data signal may not be input, which may result in the pixel PXij appearing as a bright spot.

In an embodiment of the present disclosure, the position where the j-th data line DLj and the first bridge pattern BRG1′ are connected may not overlap the position where the second semiconductor pattern ACT_T2 and the first bridge pattern BRG1′ are connected. From this, the j-th data line DLj may be prevented from being short-circuited with the second semiconductor pattern ACT_21 due to the unintentional physical impact. Furthermore, it is possible to prevent the occurrence of a bright spot due to the short circuit of the j-th data line DLj, which is caused by the failure of the data signal input.

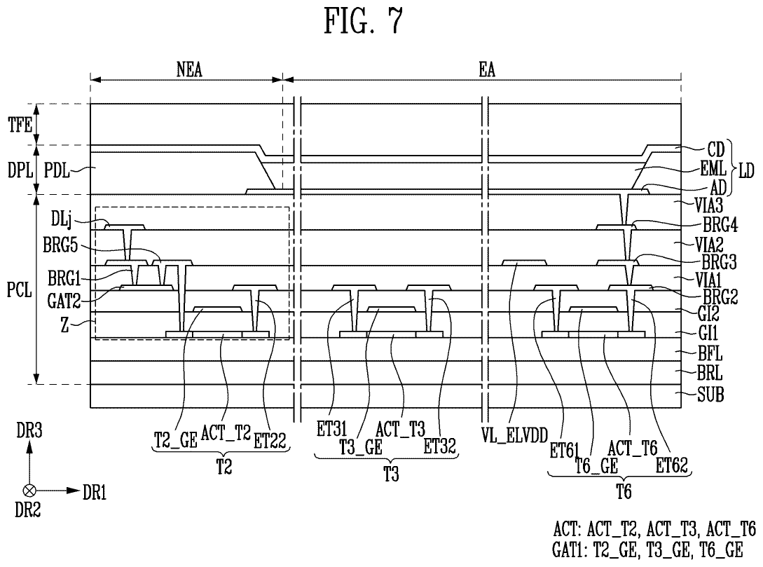

FIG. 7 is a partial cross-sectional view illustrating the stacked structure of the second transistor, third transistor, and sixth transistor areas of the pixel of FIG. 2 according to an embodiment.

Referring to FIG. 7, a pixel circuit layer PCL, a display element layer DPL, and a thin film encapsulation layer TFE may be sequentially arranged on a base layer SUB (or substrate).

The pixel circuit layer PCL may include a barrier layer BRL, a buffer layer BFL, a semiconductor layer ACT, a first insulating layer GI1, a first conductive layer GAT1, a second insulating layer GI2, a first organic layer VIA1, a second organic layer VIA2, and a third organic layer VIA3.

In the pixel circuit layer PCL, the barrier layer BRL, the buffer layer BFL, the semiconductor layer ACT, the first insulating layer GI1, the first conductive layer GAT1, the second insulating layer GI2, the first organic layer VIA1, the second organic layer VIA2, and the third organic layer may be sequentially stacked on the base layer SUB in a third direction DR3.

The second transistor T2 may include a second semiconductor pattern ACT_T2, a gate pattern T2_GE of the second transistor T2, and a second second-transistor electrode ET22.

The third transistor T3 may include a third semiconductor pattern ACT_T3, a gate pattern T3_GE of the third transistor T3, a first third-transistor electrode ET31, and a second third-transistor electrode ET32.

The sixth transistor T6 may include a sixth semiconductor pattern ACT_T6, a gate pattern T6_GE of the sixth transistor T6, a first sixth-transistor electrode ET61, and a second sixth-transistor electrode ET62.

When comparing the embodiments of FIG. 3 and FIG. 7, the embodiment of FIG. 7 may differ from the embodiment of FIG. 3 in that the embodiment of FIG. 7 includes a fifth bridge pattern BRG5 instead of the first second-transistor electrode ET21. Therefore, redundant descriptions may be omitted below.

The fifth bridge pattern BRG5 may include a plurality of patterns extending from the fifth bridge pattern BRG5. Any one of the plurality of patterns may be connected to the second conductive layer GAT2 through a contact hole penetrating the first organic layer VIA1. Another one of the plurality of patterns may be connected to the second semiconductor pattern ACT_T2 through a contact hole penetrating the first organic layer VIA1, the first insulating layer GI1, and the second insulating layer GI2. Each of the plurality of patterns may extend in the third direction and may be in a parallel form to each other.

The j-th data line DLj may be electrically connected to the second semiconductor pattern ACT_T2 through the first bridge pattern BRG1, the second conductive layer GAT2, and the fifth bridge pattern BRG5.

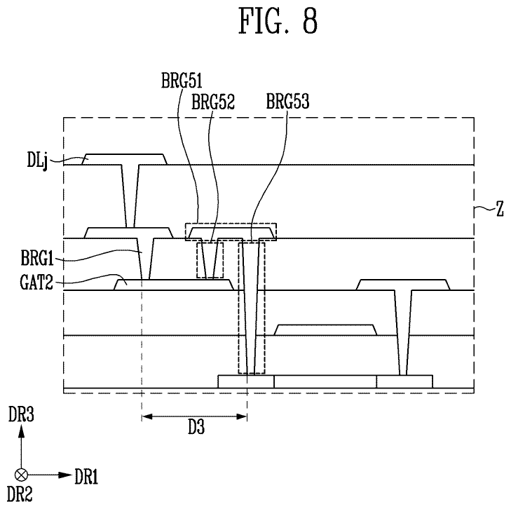

FIG. 8 is an enlarged view of the area Z of FIG. 7.

Referring to FIG. 8, the fifth bridge pattern BRG5 may include a first fifth-bridge pattern BRG51, a second fifth-bridge pattern BRG52, and a third fifth-bridge pattern BRG53.

The first fifth-bridge pattern BRG51 may be arranged on the first organic layer VIA1 and may extend in the first direction DR1.

The second fifth-bridge pattern BRG52 may be connected to the second conductive layer GAT2 through a contact hole penetrating the first organic layer VIA1. The second fifth-bridge pattern BRG52 may extend from an area of the first fifth-bridge pattern BRG51 and may extend in the third direction DR3.

The third fifth-bridge pattern BRG53 may be connected to the second semiconductor pattern ACT_T2 through a contact hole penetrating the first organic layer VIA1, the first insulating layer GI1, and the second insulating layer GI2. The third fifth-bridge pattern BRG53 may extend from the other area of the first fifth-bridge pattern BRG51 and may extend in the third direction DR3.

Here, the area of the second fifth-bridge pattern BRG52 may be spaced apart from an area of the third fifth-bridge pattern BRG53 in the first direction DR1 by a third length D3. The first fifth-bridge pattern BRG51 may be spaced apart from the first bridge pattern BRG1. The second conductive layer GAT2 may connect the second fifth-bridge pattern and the first bridge pattern BRG1 in the first direction DR1.

Accordingly, the position where the j-th data line DLj and the first bridge pattern BRG1 are connected may not overlap the position where the second semiconductor pattern ACT_T2 and the fifth bridge pattern BRG5 are connected.

During the use of the display device DD, an unintended impact may be applied toward the pixel PXij in the third direction DR3 (or in the direction perpendicular to the base layer SUB). At this time, the distance between the j-th data line DLj and the second semiconductor pattern ACT_T2 in the third direction DR3 may become shorter due to the pressing caused by the impact. If the j-th data line DLj and the second semiconductor pattern ACT_T2 are short-circuited with each other, the data signal may not be input, which may be expressed as a bright spot.

In an embodiment of the present disclosure, the position where the j-th data line DLj and the first bridge pattern BRG1 are connected may not overlap the position where the second semiconductor pattern ACT_T2 and the fifth bridge pattern BRG5 are connected. Accordingly, the j-th data line DLj may be prevented from being short-circuited with the second semiconductor pattern ACT_21 due to an unintended impact. Furthermore, it is possible to prevent the data signal from not being input and being expressed as a bright spot due to a short circuit of the j-th data line DLj.

A display device according to an embodiment is applicable to various types of electronic devices. In an embodiment, an electronic device includes the above-described display device and may further include other modules or devices having additional functions in addition to the display device.

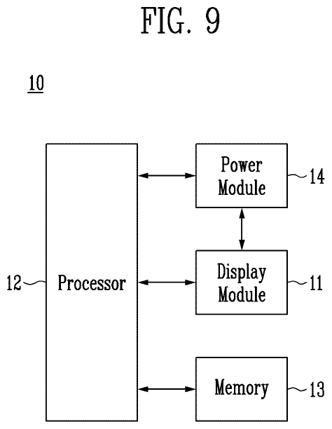

FIG. 9 is a block diagram of an electronic device according to an embodiment. Referring to FIG. 9, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

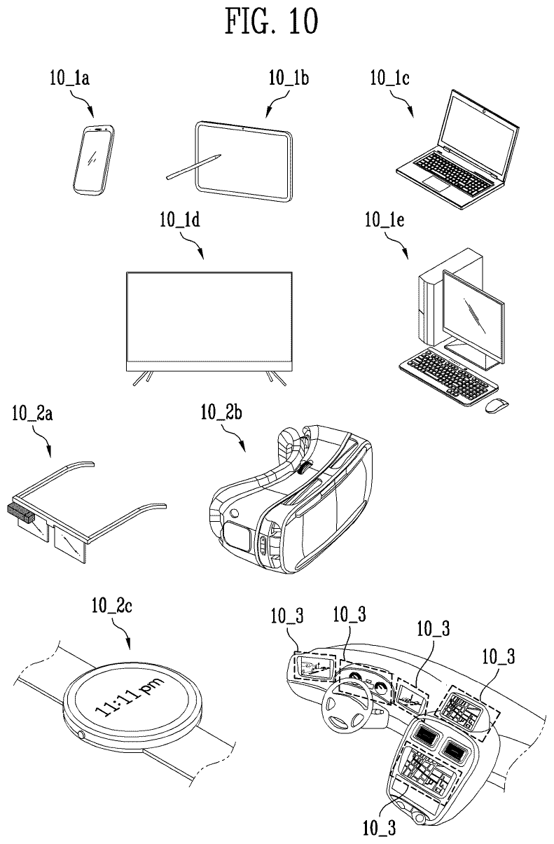

FIG. 10 shows schematic views of various embodiments of an electronic device.

Referring to FIG. 10, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device comprising:
a second semiconductor pattern and a first second-transistor electrode connected to the second semiconductor pattern in a direction perpendicular to the second semiconductor pattern;
a second conductive layer located on the first second-transistor electrode and connected to the first second-transistor electrode;
a first bridge pattern located on the second conductive layer and connected to the second conductive layer; and
a data line connected to the first bridge pattern to supply a data signal to the second semiconductor pattern,
wherein a first area where the second semiconductor pattern and the first second-transistor electrode are connected and a second area where the data line and the first bridge pattern are connected do not overlap.

2. The display device according to claim 1, wherein third area where the first second-transistor electrode is connected to the second conductive layer is spaced apart from a fourth area where the first bridge pattern is connected to the second conductive layer by a first length in a direction in which the second conductive layer extends.

3. The display device according to claim 1, wherein each of the second semiconductor pattern and the second conductive layer extends in a first direction,
the first second-transistor electrode extends in a third direction perpendicular to the first direction, and
the second conductive layer overlaps the second semiconductor pattern in a partial area.

4. The display device according to claim 1, wherein the first second-transistor electrode electrically connects the second semiconductor pattern and the second conductive layer through a contact hole penetrating first and second insulating layers located between the second semiconductor pattern and the second conductive layer.

5. The display device according to claim 4, wherein the second conductive layer comprises a first layer containing titanium and disposed on the second insulating layer, and a second layer containing molybdenum and provided on the first layer.

6. The display device according to claim 4, wherein the second conductive layer comprises a first layer containing titanium and disposed on the second insulating layer, a second layer containing aluminum and provided on the first layer, and a third layer containing titanium and provided on the second layer.

7. The display device according to claim 1, wherein the first bridge pattern is connected to the second conductive layer through a contact hole penetrating the first organic layer located between the first bridge pattern and the second conductive layer.

8. A display device comprising:
a second semiconductor pattern and a first second-transistor electrode connected to the second semiconductor pattern in a direction perpendicular to the second semiconductor pattern;
a first bridge pattern located on the first second-transistor electrode and connected to the first second-transistor electrode; and
a data line connected to the first bridge pattern to supply a data signal to the second semiconductor pattern,
wherein a first area where the second semiconductor pattern and the first second-transistor electrode are connected and a second area where the data line and the first bridge pattern are connected do not overlap.

9. The display device according to claim 8, wherein a third area where the first second-transistor electrode is connected to the first bridge pattern is spaced apart from a fourth area where the data line is connected to the first bridge pattern by a second length in a direction in which the first bridge pattern extends.

10. The display device according to claim 8, wherein each of the second semiconductor pattern and the first bridge pattern extends in a first direction,
the first second-transistor electrode extends in a third direction perpendicular to the first direction, and
the first bridge pattern overlaps the second semiconductor pattern in a partial area.

11. The display device according to claim 8, wherein the first second-transistor electrode is connected to the first bridge pattern through a contact hole penetrating a first insulating layer, a second insulating layer, and a first organic layer located between the first bridge pattern and the second semiconductor pattern.

12. The display device according to claim 8, wherein the data line is connected to the first bridge pattern through a contact hole penetrating the second organic layer located between the first bridge pattern and the data line.

13. An electronic device, comprising:
a processor to provide input image data; and
a display device to display an image based on the input image data,
the display device comprising:
a second semiconductor pattern and a second conductive layer located on the second semiconductor pattern;
a fifth bridge pattern located on the second semiconductor pattern and the second conductive layer to electrically connect the second semiconductor pattern and the second conductive layer;
a first bridge pattern located on the second conductive layer and connected to the second conductive layer; and
a data line connected to the first bridge pattern to supply a data signal to the second semiconductor pattern,
wherein a first area where the second semiconductor pattern and the fifth bridge pattern are connected and a second area where the data line and the first bridge pattern are connected do not overlap.

14. The electronic device according to claim 13, wherein the fifth bridge pattern comprises a first fifth-bridge pattern and a second fifth-bridge pattern and a third fifth-bridge pattern extending in a direction perpendicular to the second semiconductor pattern from the first fifth-bridge pattern,
the second fifth-bridge pattern is connected to the second conductive layer through a contact hole penetrating a first organic layer located between the first fifth-bridge pattern and the second conductive layer, and
the third fifth-bridge pattern is connected to the second semiconductor pattern through a contact hole penetrating a first insulating layer, a second insulating layer, and a first organic layer located between the first fifth-bridge pattern and the second semiconductor pattern.

15. The electronic device according to claim 14, wherein the second conductive layer comprises a first layer containing titanium and arranged on the second insulating layer, and a second layer containing molybdenum and provided on the first layer.

16. The electronic device according to claim 14, wherein the second conductive layer comprises a first layer containing titanium and arranged on the second insulating layer, a second layer containing aluminum and provided on the first layer, and a third layer containing titanium and provided on the second layer.

17. The electronic device according to claim 14, wherein a third area where the third fifth-bridge pattern is connected to the second semiconductor pattern is spaced apart from a fourth area where the first bridge pattern is connected to the second conductive layer by a third length in a direction in which the second conductive layer extends.

18. The electronic device according to claim 13, wherein the first bridge pattern is connected to the second conductive layer through a contact hole penetrating a first organic layer located between the first bridge pattern and the second conductive layer.
